(19) United States
(12) Patent Application Publication
(10) Pub. No.: US 2026/0311738 A1
(43) Pub. Date: Oct. 8, 2026

(54) HBM POWER UP PROTECTION SCHEME DESIGN

(71) Applicant: Micron Technology, Inc., Boise, ID (US)

(72) Inventor: Yantao Ma, Meridian, ID (US)

(21) Appl. No.: 19/550,627

(22) Filed: Feb. 26, 2026

Related U.S. Application Data
(60) Provisional application No. 63/784,805, filed on Apr. 7, 2025.

(51) Int. Cl. G11C 11/4074; H10B 80/00; H10W 90/20

(52) U.S. Cl. CPC G11C 11/4074; H10B 80/00; H10W 90/297

(57) ABSTRACT

Systems and methods are provided for implementing a power up protection scheme designed for a memory device, such as an HBM device, to coordinate the power up process of the interface die and the memory dies to improve the performance of the memory device and reduce or avoid errors in operations. The status of the power supplies for the interface die and the memory dies are monitored. In some embodiments, the interface die and the memory dies are powered up serially after the corresponding power supplies used for the power up process are detected to be in the ready status. In some embodiments, the interface die and the memory dies are powered up in parallel after all power supplies are detected to be in the ready status.

### CROSS-REFERENCE TO RELATED APPLICATIONS

This application claims priority to U.S. Provisional Application No. 63/784,805, filed Apr. 07, 2025, which is incorporated by reference herein in its entirety.

### BACKGROUND OF THE INVENTION

### Field of The Present Disclosure

The present disclosure relates generally to the field of semiconductor memory devices. More specifically, embodiments of the present disclosure relate to power up protection of a memory device (e.g., a high band memory (HBM) device).

### Description of Related Art

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light and not as admissions of prior art.

A memory device may include a number of dies, and each die may include a number of memory arrays and peripheral circuitry thereon, such as die logic or a die processor. The memory device may be a high bandwidth memory (HBM) device, which may include an interface die (or base die/logic die) and one or more memory dies (e.g., internal memory dies) stacked on the interface die. The interface die includes interface circuitry to communicate with a host device through a communication interface. The internal memory dies may communicate information with the interface die. For example, the memory device may receive commands or operations from the host device through the communication interface of the interface die, such as read or write operations to transfer data (e.g., user data and associated integrity data, such as error data or address data, etc.) between the memory device and the host device, erase operations to erase data from the memory device, or drive management operations (e.g., data migration, garbage collection, block retirement), etc. The interface die may communicate with the internal memory dies and operate together to complete the operations. However, timing variations may exist between the power up of the internal memory dies and the interface die due to different power supplies used or variations in process, voltage, and temperature (PVT). It may be desirable to use a power up protection scheme to manage the power up process of the interface die and the internal memory dies.

Embodiments of the present disclosure may be directed to address one or more of the problems set forth above.

### BRIEF DESCRIPTION OF THE DRAWINGS

Various aspects of this disclosure may be better understood upon reading the following detailed description and upon reference to the drawings in which:

FIG. 1 is a cross-section of an embodiment of a system including a memory device and a host device, according to an embodiment of the present disclosure;

FIG. 2 is a simplified block diagram showing a perspective view of a portion of the memory device of FIG. 1, according to an embodiment of the present disclosure;

FIG. 3 is a simplified block diagram illustrating certain features of the memory device of FIG. 1, according to an embodiment of the present disclosure;

FIG. 4 is a timing diagram illustrating an embodiment of a power up and power off sequence of various power supplies used for the memory device of FIG. 1, according to an embodiment of the present disclosure;

FIG. 5 is a flow chart illustrating an embodiment of a method for monitoring the power up status of power supplies to coordinate the power up process of the memory device of FIG. 1, according to an embodiment of the present disclosure;

FIG. 6 is a flow chart illustrating another embodiment of a method for monitoring the power up status of power supplies to coordinate the power up process of the memory device of FIG. 1, according to an embodiment of the present disclosure; and

FIG. 7 is a flow chart illustrating another embodiment of a method for monitoring the power up status of power supplies to coordinate the power up process of the memory device of FIG. 1, according to an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As mentioned previously, a memory device may be a high bandwidth memory (HBM) device, which may include an interface die (or base die/logic die) and one or more memory dies (e.g., internal memory dies) stacked on the interface die to form a vertically stacked three-dimensional (3D) HBM cube. The interface die includes a physical layer (PHY) interface to communicate with a host device. The interface die also includes circuitry to communicate with the other memory dies of the HBM device. The interface die and the memory dies may exchange signals and coordinate together to complete commands or operations (e.g., read, write, reset). However, with an unmanaged power up scheme, the interface die may not be powered up and available to provide information (e.g., a parameter) when the memory dies need the information, and vice versa. For instance, external power supplies may be used by the interface die and the memory dies, which may cause variations in power up process of the interface die and the memory dies. For example, external power supplies may be coupled to the interface die and the memory dies through different routes, and the routing, coupling, and loading differences may cause variations in the power up process of the interface die and the memory dies. In some embodiments, different power supplies (e.g., with or without stagger) may be applied to different dies (e.g., the interface die, the memory dies), which may cause unmanaged power up ramping sequences. For example, the different power supplies may be powered up using different power up ramping ratios and/or having different predefined values at ready status (e.g., the stabilized maximum value), which may cause the different power supplies to be ready at different times. For instance, the interface die may use power supplies VPP, VDDQ, VDDC, etc. while the memory dies may use VPP, VDD, etc., and the power supplies VPP, VDD, VDDQ, and VDDC may have different predefined values at ready status and/or may be powered up using different ramping ratios.

In addition, in some embodiments, variations in process, voltage, and temperature (PVT) may also cause the interface die and memory dies to be powered up at different times. For example, the trip points of the power supplies for the interface die and memory dies may have different PVT variations, which may cause the interface die and the memory dies to be powered up at different times.

The unmanaged power up scheme may cause errors in operations, such as risks in initializations of the memory dies, and the like. For example, the memory dies may use information of a parameter (e.g., memory die address) from drivers (e.g., Through-Wafer-Interconnect (TWI) drivers, such as Through-Silicon-Via (TSV) drivers) on the interface die, but the drivers may be disabled during the power up process of the interface die. The interface die may also use information from components on the memory dies, but the components may be disabled or reset during the power up process of the memory dies. Accordingly, it may be desirable to implement an improved power up protection scheme for the memory device to coordinate the power up process of the interface die and the memory dies.

Accordingly, the present disclosure is directed to methods and systems for implementing a power up protection scheme designed for a memory device (e.g., a HBM device) to coordinate the power up process of the interface die and the memory dies by monitoring the status of the corresponding power supplies. The interface die and the memory dies may use different power supplies. In some embodiments, the interface die and the memory dies may be powered up serially after the corresponding power supplies used for the power up process are detected to be in a ready status (e.g., the stabilized maximum value). In some embodiments, the interface die and the memory dies may be powered up in parallel after all power supplies are detected to be in the ready status.

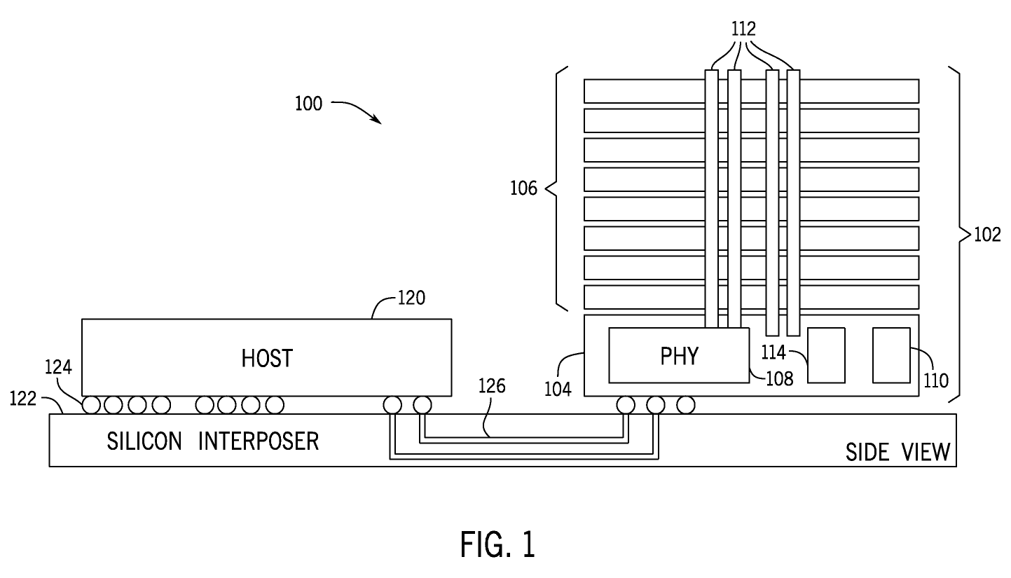

Turning now to the figures, FIG. 1 is a cross-section of a system 100 including a memory device and a host device according to an embodiment of the present disclosure. Although one memory device is shown for the depicted example, a number of memory devices greater than one may be used. A memory device 102, as shown in the embodiment of FIG. 1, may be a high bandwidth memory (HBM) device (e.g., HBM cube), which includes an interface die (or base die) 104 and one or more memory dies 106 stacked on the interface die 104. The interface die 104 may include a physical layer (PHY) 108, which may be used as an interface for the physical transmission of data between the HBM device and the host device. The interface die 104 may include a power supply circuit 110 to receive external power supply signals (e.g., VPP, VDD, VDDC, VDDQ, VDDQL), which may be used to power up the interface die 104. In some embodiments, the power supply circuit 110 may be included in the PHY 108. The power supply circuit 110 may be used to monitor the status of the external power supplies for the interface die 104. In some embodiments, the external power supply signals may also include the power supply signals that may be used to power up the memory dies 106. The power supply circuit 110 may be used to monitor the status of the external power supplies for the interface die 104 and the memory dies 106.

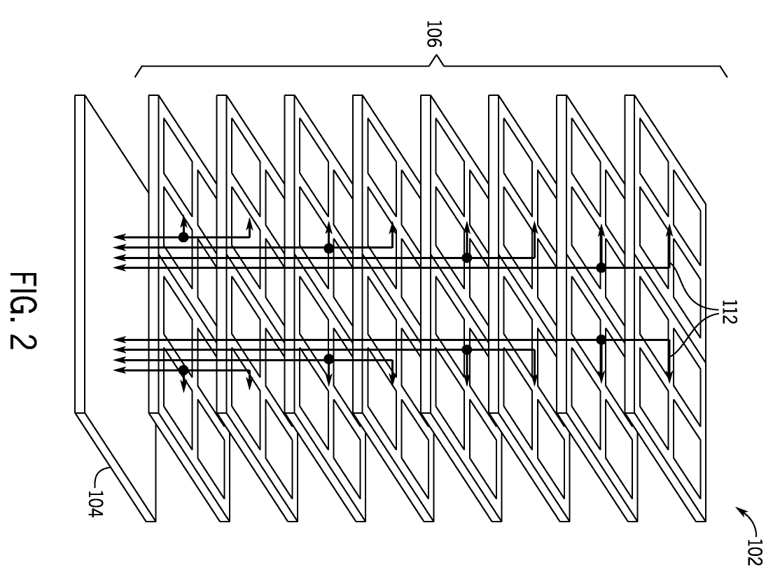

The memory device 102 may include one or more Through-Wafer-Interconnects (TWIs) 112 (if the integrated circuits are silicon-based, these may also be known as Through-Silicon-Vias (TSVs)) to couple the interface die 104 and the memory dies 106. In some embodiments, wire bond interconnections may be used instead of TWIs to couple the interface die 104 and the memory dies 106. The TWIs 112 may be used to communicate commands or data between the interface die 104 and the memory dies 106, as illustrated in FIG. 2. Communications through the TWIs 112 may be driven by one or more drivers 114 located on the interface die 104.

FIG. 2 is a simplified block diagram showing a perspective view of a portion of the memory device 102. As illustrated in FIG. 2, the interface die 104 may be communicatively coupled to the TWIs 112, and each of the memory dies 106 may include interface circuitry to communicate with the interface die 104 via the TWIs 112.

Returning to FIG. 1, the system 100 may include a host device 120. The host device 120 and the memory device 102 may be coupled to an interposer 122 (e.g., a silicon interposer) via a number of micro-bumps 124. The interposer 122 may include channels 126, which may be used to communicatively couple the host device 120 with the memory device 102 via corresponding micro-bumps 124. Although only two channels 126 are shown in FIG. 1, greater or fewer numbers of channels 126 may be used.

The host device 120 may be coupled to the memory device 102 via the PHY 108 of the interface die 104, as illustrated in FIG. 1. The memory device 102 may receive commands or operations from the host device 120 through the channels 126 and the PHY 108, such as read or write operations to transfer data (e.g., user data and associated integrity data, such as error data or address data, etc.) between the memory device 102 and the host device 120, erase operations to erase data from the memory device 102, or drive management operations (e.g., data migration, garbage collection, block retirement), etc. The commands or operations received by the interface die 104 from the host device 120 may be communicated to the memory dies 106 via the TWIs 112. The memory dies 106 may communicate command and data with the interface die 104 via the TWIs 112. Thus, the interface die 104 and the memory dies 106 may operate together to complete the commands or operations.

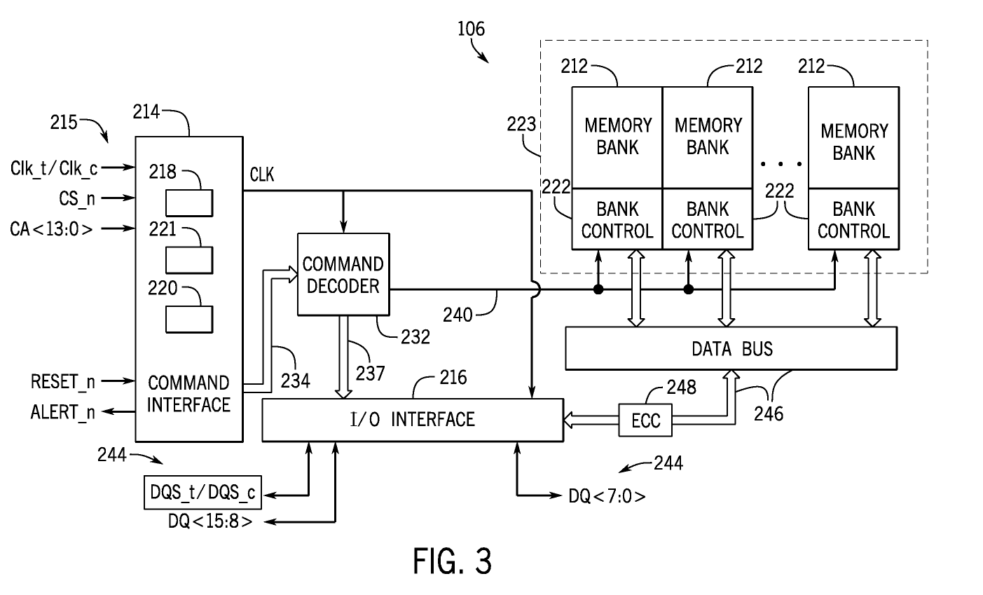

FIG. 3 is a simplified block diagram illustrating certain features of the dies 106 of the memory device 102. Specifically, the block diagram of FIG. 3 is a functional block diagram illustrating certain functionality of the dies 106. In accordance with one embodiment, each of the memory dies 106 may be a dynamic random access memory (DRAM).

Each of the memory dies 106 may include a number of memory banks 212. The memory banks 212 may be DRAM memory banks, for instance. Each of the memory dies 106 may include a command interface 214 and an input/output (I/O) interface 216 to exchange (e.g., receive and transmit) signals with the interface die 104. For example, the I/O interface 216 may exchange signals with the interface die 104 via the TWIs 112. In some embodiments, wire bond interconnections may be used in the I/O interface 216 (e.g., instead of the TWIs 112 or together with the TWIs 112) to exchange signals with the interface die 104. The command interface 214 may receive a number of signals (e.g., signals 215) from the interface die 104. The interface die 104 may provide various signals 215 to the memory dies 106 to facilitate the transmission and receipt of data to be written to or read from the dies 106. In some embodiments, some of the signals 215 may be provided to the memory dies 106 via the I/O interface 216.

As will be appreciated, the command interface 214 may include a number of circuits, such as a clock input circuit 218, a command/address input circuit 220, and a power supply circuit 221, for instance, to ensure proper handling of the signals 215. The command interface 214 may receive one or more clock signals from the interface die 104. Generally, HBM memory utilizes a differential pair of system clock signals, referred to herein as the true clock signal (Clk_t) and the complementary clock signal (Clk_c). The positive clock edge for HBM refers to the point where the rising true clock signal Clk_t crosses the falling complementary clock signal Clk_c, while the negative clock edge indicates that transition of the falling true clock signal Clk_t and the rising of the complementary clock signal Clk_c. Commands (e.g., read command, write command, etc.) are typically entered on the positive edges of the clock signal and data is transmitted or received on both the positive and negative clock edges.

The clock input circuit 218 receives the true clock signal (Clk_t) and the complementary clock signal (Clk_c) and generates an internal clock signal CLK, which is supplied to the I/O interface 216, for instance, and is used as a timing signal for determining an output timing of read data. The internal clock signal CLK may also be provided to various other components within the dies 106 and may be used to generate various additional internal clock signals. For instance, the internal clock signal CLK may be provided to a command decoder 232. The command decoder 232 may receive command signals from a command bus 234 and may decode the command signals to provide various internal commands. The command decoder 232 may also provide command signals to the I/O interface 216 over a bus 237 to facilitate receiving and transmitting I/O signals. The clock signal CLK may also be used to clock data through the I/O interface 216, for instance.

Further, the command decoder 232 may decode commands received from the command bus 234, such as read commands, write commands, mode-register set commands, activate commands, etc., and provide access to a particular memory bank 212 corresponding to the command, via the bus path 240. As will be appreciated, the dies 106 may include various other decoders, such as row decoders and column decoders, to facilitate access to the memory banks 212. In one embodiment, each memory bank 212 includes a bank control block 222 which provides the necessary decoding (e.g., row decoder and column decoder), as well as other features, such as timing control and data control, to facilitate the execution of commands to and from the memory banks 212. A group of the memory banks 212 may be included in a memory channel 223, and the memory dies 106 may include one or more channels.

The memory dies 106 execute operations, such as read commands and write commands, based on the command/address signals received from the interface die 104. In one embodiment, the command/address bus may be a 14-bit bus to accommodate the command/address signals (CA<13:0>). The command/address signals are clocked to the command interface 214 using the clock signals (Clk_t and Clk_c). The command/address input circuit 220 in the command interface 214 may receive and transmit the commands to provide access to the memory banks 212, through the command decoder 232, for instance. In addition, the command interface 214 may receive a chip select signal (CS_n). The chip select signal CS_n enables the dies 106 to process commands on the incoming command/address signals CA<13:0> for the memory chip selected by the chip select signal CS_n. Accordingly, access to specific banks 212 within the dies 106 is facilitated by the information encoded on the chip select signal CS_n and the command/address signals CA<13:0>.

In addition, the command interface 214 may receive a number of other command signals. For instance, a reset command (RESET_n) may be used to reset the command interface 214, status registers, state machines and the like, during power-up for instance. The command interface 214 may also be used to provide an alert signal (ALERT_n) to the system processor or controller for certain errors that may be detected. For instance, an alert signal (ALERT_n) may be transmitted from the dies 106 if a cyclic redundancy check (CRC) error is detected. Other alert signals may also be generated. Further, the bus and pin for transmitting the alert signal (ALERT_n) from the dies 106 may be used as an input pin during certain operations, such as the connectivity test mode executed using the TEN signal, as described above.

Data may be sent to and from the memory dies 106, utilizing the command and clocking signals discussed above, by transmitting and receiving data signals 244 through the I/O interface 216. More specifically, the data may be sent to or retrieved from the memory banks 212 over the data bus 246, which includes a plurality of bi-directional data buses. The Data I/O signals, generally referred to as DQ signals, are generally transmitted and received in one or more bi-directional data busses. In certain embodiments, an error correction code (ECC) system 248 may be used to detect, and in some cases, resolve, data errors that may arise. For example, incorrect bits may be retrieved via a memory read command and the ECC system 248 may detect, and in some cases correct, the read data. The ECC system 248 may additionally raise a flag if, for example, correction may not be possible.

To allow for higher data rates within the dies 106, certain memory devices, such as HBM memory devices, may utilize data strobe signals, generally referred to as DQS signals. The DQS signals are driven by the external processor or controller sending the data (e.g., for a write command) or by the dies 106 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the data strobe (DQS) signals may be provided as a differential pair of data strobe signals (DQS_t and DQS_c) to provide differential pair signaling during reads and writes.

The power supply circuit 221 may be used to receive external power supply signals (e.g., VDD, VPP, VDDQL), which may be used to power up the corresponding memory die 106. The power supply circuit 221 may be used to monitor the status of the external power supplies. In some embodiments, each of the memory dies 106 may include a respective power supply circuit 221 to monitor the status of the respective external power supplies used to power up the corresponding memory die. In some embodiments, the power supply circuit 110 may be used to monitor the status of all external power supplies used for the memory device 102, including both the interface die 104 and the memory dies 106.

As will be appreciated, various other components such as mode registers (to define various modes of programmable operations and configurations), read/write amplifiers (to amplify signals during read/write operations), temperature sensors (for sensing temperatures of the dies), electrical sensors (for detecting voltage or current of power supplies or other components), etc., may also be incorporated into the dies 106. Accordingly, it should be understood that the block diagram of FIG. 3 is only provided to highlight certain functional features of the dies 106 to aid in the subsequent detailed description.

As discussed above, data may be written to and read from the dies 106, for example, by the host device 120 whereby the memory dies 106 operate as volatile memory, such as HBM memory. The host device 120 may, in some embodiments, also include separate non-volatile memory, such as read-only memory (ROM), PC-RAM, silicon-oxide-nitride-oxide-silicon (SONOS) memory, metal-oxide-nitride-oxide-silicon (MONOS) memory, polysilicon floating gate based memory, and/or other types of flash memory of various architectures (e.g., NAND memory, NOR memory, etc.) as well as other types of memory devices (e.g., storage), such as solid state drives (SSD’s), MultimediaMediaCards (MMC’s), SecureDigital (SD) cards, CompactFlash (CF) cards, or any other suitable device. Further, it should be appreciated that the host device 120 may include one or more external interfaces, such as Universal Serial Bus (USB), Peripheral Component Interconnect (PCI), PCI Express (PCI-E), Small Computer System Interface (SCSI), IEEE 1394 (Firewire), or any other suitable interface as well as one or more input devices to allow a user to input data into the host device 120, for example, buttons, switching elements, a keyboard, a light pen, a stylus, a mouse, and/or a voice recognition system, for instance. The host device 120 may optionally also include an output device, such as a display coupled to the processor and a network interface device, such as a Network Interface Card (NIC), for interfacing with a network, such as the Internet. As will be appreciated, the host device 120 may include many other components, depending on the application of the host device 120.

As discussed above, the interface die 104 and the memory dies 106 may exchange signals and coordinate together to complete commands or operations (e.g., read, write, reset). However, with an unmanaged power up scheme, the interface die 104 may not be powered up and available to provide information (e.g., a parameter ) when the memory dies 106 need the information, and vice versa. For instance, external power supplies may be used by the interface die 104 and the memory dies 106, which may cause variations in power up process of the interface die 104 and the memory dies 106. For example, external power supplies may be coupled to the interface die 104 and the memory dies 106 through different routes, and the routing, coupling, and loading differences may cause variations in the power up process of the interface die 104 and the memory dies 106. In some embodiments, different power supplies (e.g., with or without stagger) may be applied to different dies (e.g., the interface die 104, the memory dies 106), which may cause unmanaged power up ramping sequences as described with regard to FIG. 4 below. For example, the different power supplies may be powered up using different power up ramping ratios and/or having different predefined values at ready status (e.g., the stabilized maximum value), which may cause the different power supplies to be ready at different times. For instance, the interface die 104 may use power supplies VPP, VDDQ, VDDC, etc. while the memory dies 106 may use VPP, VDD, etc., and the power supplies VPP, VDD, VDDQ, and VDDC may have different predefined values at ready status and/or may be powered up using different ramping ratios.

In addition, in some embodiments, variations in process, voltage, and temperature (PVT) may also cause the interface die 104 and memory dies 106 to be powered up at different times. For example, the trip points of the power supplies for the interface die 104 and memory dies 106 may have different PVT variations, which may cause the interface die 104 and memory dies 106 to be powered up at different time.

The unmanaged power up scheme may cause errors in operations, such as risks in initializations of the memory dies 106, and the like. For example, the memory dies 106 may use information of a parameter (e.g., memory die address) from drivers for the TWIs (e.g., TSVs) on the interface die 104, but the drivers may be disabled during power up process of the interface die 104. The interface die 104 may also use information of a parameter from components on the memory dies 106, but the components may be disabled or reset during the power up process of the memory dies 106. Accordingly, the embodiments described herein provide an improved power up protection scheme for the memory device 102 to coordinate the power up process of the interface die 104 and the memory dies 106.

FIG. 4 is a timing diagram 300 illustrating an embodiment of a power up and power off sequence of various power supplies. In FIG. 4, a curve 302 shows the power up and power off timing of the voltage supply VPP, which has a predefined value V1 (e.g., the stabilized maximum value) at ready status; a curve 304 shows the power up and power off timing of the voltage supply VDDC, which has a predefined value V2 (e.g., the stabilized maximum value) at ready status; a curve 306 shows the power up and power off timing of the voltage supply VDDQ, which has a predefined value V3 (e.g., the stabilized maximum value) at ready status; and a curve 308 shows the power up and power off timing of the voltage supply VDDQL, which has a predefined value V4 (e.g., the stabilized maximum value) at ready status. The power supplies VPP, VDDC, VDDQ, and VDDQL may have different predefined values (e.g., V1>V2>V3>V4, as illustrated in FIG. 4) at ready status (e.g., the stabilized maximum value) and may be powered up using different ramping ratios. Accordingly, it may take different times for the different power supplies to be powered up and ready.

For example, at time T1, the power supply VPP may be powered up and at ready status with the predefined value of V1 (e.g., the stabilized maximum value) as indicated by the horizontal portion of the curve 302, while the other power supplies (e.g., VDDC, VDDQ, VDDQL) may not be powered up and at ready status yet, as indicated by respective horizontal portions of the curves 304, 306, and 308. Since the interface die 104 may use power supplies VPP, VDDQ, and VDDC while the memory dies 106 may use VPP and VDD, the memory dies 106 may be powered up at time T1 while the interface die 104 may not be powered up at T1 due to the power supplies VDDQ and VDDC not being ready at T1. At time T2 all the power supplies (e.g., VPP, VDDC, VDDQ, VDDQL) are powered up and ready (e.g., the stabilized maximum value), accordingly, both the memory dies 106 and the interface dies 104 may be powered up at time T2. Therefore, a power up protection scheme may be designed for the memory device 102 to coordinate the power up process of the interface die 104 and the memory dies 106 by monitoring the status of the corresponding power supplies.

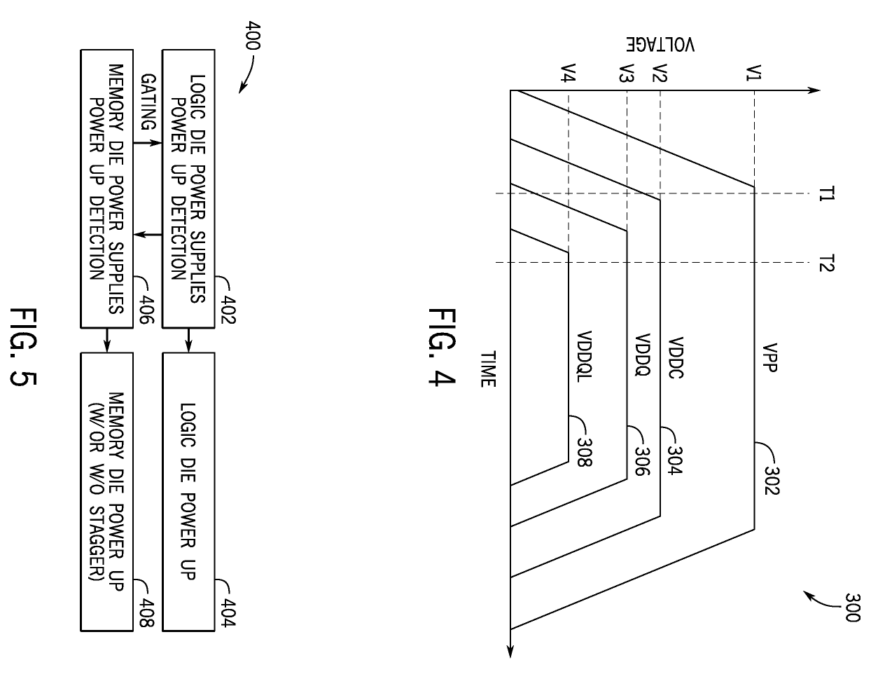

FIG. 5 is a flowchart illustrating an embodiment of a method 400 for monitoring the power up status of power supplies to coordinate the power up process of the memory dies 106 and the interface die 104. At block 402, the status of the power supplies for the power up process of the interface die 104 may be monitored (e.g., by electrical sensors), and the interface die 104 may be powered up at block 404 only when all the power supplies used for the power up process of the interface die 104 are detected to be in the ready status (e.g., the stabilized maximum value). After the interface die 104 is powered up, at block 406, the status of the power supplies for the power up process of the memory dies 106 may be monitored, and the memory dies 106 may be powered up at block 408, only when all the power supplies used for the power up process of the memory dies 106 are detected to be in the ready status (e.g., the stabilized maximum value).

In the embodiment illustrated in FIG. 5, the interface die 104 and the memory dies 106 are powered up serially (i.e., one after the other). It should be noted that the method 400 may be performed in any suitable order and is not limited to the order presented above. For example, in some embodiments, the power supplies for the memory dies 106 may be in the ready status (e.g., the stabilized maximum value) before the power supplies for the interface dies 104, and the memory dies 106 may be powered up before the interface die 104 (e.g., the power up process of the memory dies 106 may not use any information from the interface die 104). The interface die 104 may then be powered up after the memory dies 106 are powered up. Therefore, block 406 and block 402 may switch the performing order. Thus, the block 406 may be performed before the block 402 to detect the status of the power supplies for the power up process of the memory dies 106, and the memory dies 106 may be powered up at block 408 when all the power supplies used for the power up process of the memory dies 106 are detected to be in the ready status (e.g., being the stabilized maximum value). Then, after the memory dies 106 are powered up, the block 402 may be performed to detect the power supplies for the power up process of the interface die 104, and the interface die 104 may be powered up at block 404 when all the power supplies used for the power up process of the interface die 104 are detected to be in the ready status (e.g., the stabilized maximum value). In some embodiments, the order to power up the interface die 104 and the memory dies 106 may depend on the power up process of the interface die 104 and the memory dies 106. For example, in some embodiments, the power up process of the memory dies 106 may use information from the interface die 104, and therefore, the interface die 104 may be powered up before the memory dies 106 could be powered up, and vice versa.

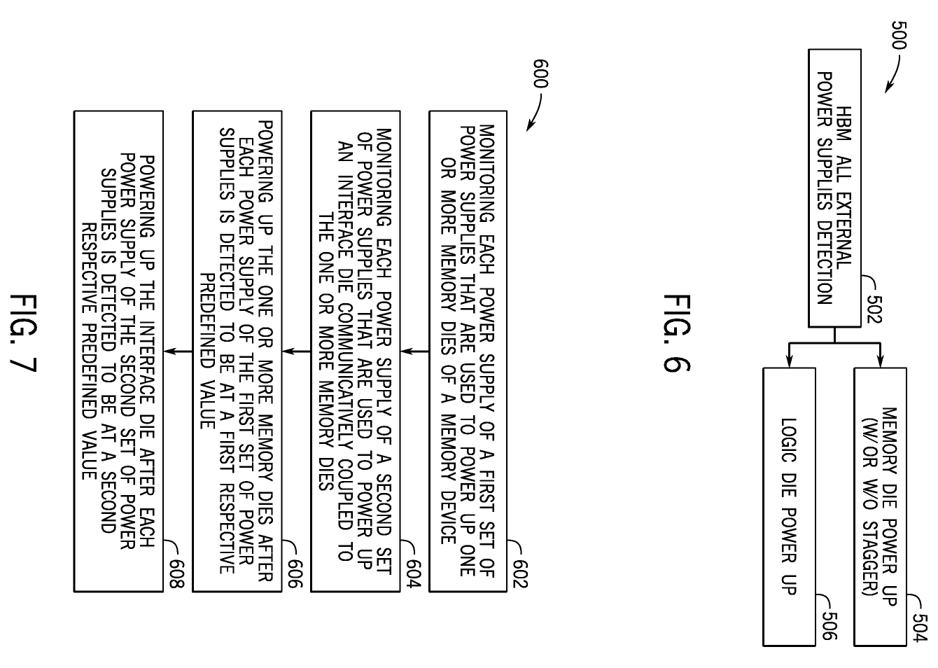

FIG. 6 is a flowchart illustrating another embodiment of a method 500 for monitoring the power up status of power supplies to coordinate the power up process of the memory dies 106 and the interface die 104. At block 502, the status of all power supplies (e.g., all external power supplies of the HBM device, such as VPP, VDDC, VDDQ, VDDQL) for the power up process of the interface die 104 and the memory dies 106 may be monitored. When all power supplies are detected to be in the ready status (e.g., the stabilized maximum value), the memory dies 106 may be powered up at block 504 and the interface die 104 may be powered up at block 506 independently. In the embodiment illustrated in FIG. 6, the interface die 104 and the memory dies 106 may be powered up in parallel. Therefore, the interface die 104 and the memory dies 106 may be powered up independently after all power supplies are detected to be in the ready status, without waiting for the completion of the power up process of the other. In some embodiments, the power up process of the interface die 104 may depend on the power up process of the memory dies 106, or vice versa. For example, in some embodiments, the power up process of the interface die 104 may use information from the memory dies 106, and the information may not be available before the memory dies 106 are powered up, or vice versa. Therefore, in these embodiments, after all power supplies are detected to be in the ready status at block 502, the interface die 104 may be powered up before the memory dies 106 could be powered up, or vice versa.

FIG. 7 is a flow chart illustrating another embodiment of a method 600 for monitoring the power up status of power supplies to coordinate the power up process of the memory dies 106 and the interface die 104. At block 602, each power supply of a first set of power supplies that are used to power up the memory dies 106 may be monitored (e.g., by electrical sensors). At block 604, each power supply of a second set of power supplies that are used to power up the interface die 104 may be monitored (e.g., by electrical sensors). At block 606, the memory dies 106 may be powered up after each power supply of the first set of power supplies is detected to be at a first respective predefined value (e.g., the stabilized maximum value). At block 608, the interface die 104 may be powered up after each power supply of the second set of power supplies is detected to be at a second respective predefined value (e.g., the stabilized maximum value). It should be noted that the method 600 may be performed in any suitable order and is not limited to the order presented above.

In the embodiment illustrated in FIG. 7, the interface die 104 and the memory dies 106 may be powered up serially (i.e., one after the other) or in parallel. For example, in some embodiments, the block 602 may be performed first and then the block 606 may be performed so that the memory dies 106 may be powered up first. After the memory dies 106 are powered up, the block 604 may be performed and then the block 608 may be performed so that the interface die 104 may be powered up. In some embodiments, the block 602 and the block 604 may be performed first, and then the block 606 and the block 608 may be performed in parallel so that the memory dies 106 and the interface die 104 may be powered up in parallel.

Accordingly, the technical effects of the present disclosure include methods and systems for implementing a power up protection scheme designed for a memory device (e.g., a HBM device) to coordinate the power up process of the interface die and the memory dies by monitoring the status of the corresponding power supplies. In some embodiments, the interface die and the memory dies may be powered up serially after the corresponding power supplies used for the power up process are detected to be in the ready status (e.g., the stabilized maximum value). In some embodiments, the interface die and the memory dies may be powered up in parallel after all power supplies are detected to be in the ready status.

In the illustrated embodiments above, the memory devices and systems are primarily described in the context of devices incorporating DRAM storage media. Memory devices configured in accordance with other embodiments of the present technology, however, may include other types of memory devices and systems incorporating other types of storage media, including PCM, SRAM, FRAM, RRAM, MRAM, read only memory (ROM), erasable programmable ROM (EPROM), electrically erasable programmable ROM (EEROM), ferroelectric, magnetoresistive, and other storage media, including non-volatile, flash (e.g., NAND and/or NOR) storage media.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function]…” or “step for [perform]ing [a function]…”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An apparatus, comprising:
one or more memory dies configured to be powered up by a first set of power supplies;
an interface die communicatively coupled to the one or more memory dies and configured to be powered up by a second set of power supplies; and
a power supply circuit configured to:
monitor each power supply of the first set of power supplies;
monitor each power supply of the second set of power supplies;
power up the one or more memory dies after each power supply of the first set of power supplies is detected to be at a first respective predefined value; and
power up the interface die after each power supply of the second set of power supplies is detected to be at a second respective predefined value.

2. The apparatus of claim 1, wherein the first set of power supplies comprises at least one power supply that is not included in the second set of power supplies.

3. The apparatus of claim 1, wherein the interface die is powered up before the one or more memory dies are powered up.

4. The apparatus of claim 3, wherein a parameter is used when powering up the one or more memory dies, and wherein the parameter is available after the interface die is powered up.

5. The apparatus of claim 1, wherein the one or more memory dies are powered up before the interface die is powered up.

6. The apparatus of claim 5, wherein a parameter is used when powering up the interface die, and wherein the parameter is available after the one or more memory dies are powered up.

7. The apparatus of claim 1, wherein the one or more memory dies are powered up independently to the interface die.

8. The apparatus of claim 1, wherein the power supply circuit is configured to detect the first respective predefined value and the second respective predefined value before powering up the one or more memory dies or the interface die.

9. An interface die of a memory device, comprising:
a PHY communicatively coupled to one or more memory dies of the memory device via one or more Through-Wafer-Interconnects (TWIs); and
a power supply circuit configured to:
monitor each power supply of a first set of power supplies that are used to power up the one or more memory dies;
monitor each power supply of a second set of power supplies that are used to power up the interface die;
power up the one or more memory dies after each power supply of the first set of power supplies is detected to be at a first respective predefined value; and
power up the interface die after each power supply of the second set of power supplies is detected to be at a second respective predefined value.

10. The interface die of claim 9, wherein the first set of power supplies comprises at least one power supply that is not included in the second set of power supplies.

11. The interface die of claim 9, wherein the interface die is powered up before the one or more memory dies are powered up.

12. The interface die of claim 11, wherein a parameter is used when powering up the one or more memory dies, and wherein the parameter is available after the interface die is powered up.

13. The interface die of claim 12, wherein the parameter comprises information from a driver for the one or more TWIs.

14. The interface die of claim 9, wherein the one or more memory dies are powered up before the interface die is powered up.

15. The interface die of claim 14, wherein a parameter is used when powering up the interface die, and wherein the parameter is available after the one or more memory dies are powered up.

16. The interface die of claim 9, wherein the one or more memory dies are powered up independently to the interface die.

17. A method, comprising:
monitoring each power supply of a first set of power supplies that are used to power up one or more memory dies of a memory device;
monitoring each power supply of a second set of power supplies that are used to power up an interface die communicatively coupled to the one or more memory dies;
powering up the one or more memory dies after each power supply of the first set of power supplies is detected to be at a first respective predefined value; and
powering up the interface die after each power supply of the second set of power supplies is detected to be at a second respective predefined value.

18. The method of claim 17, wherein the first set of power supplies comprises at least one power supply that is not included in the second set of power supplies.

19. The method of claim 17, comprising:
detecting the first respective predefined value and the second respective predefined value before powering up the one or more memory dies and the interface die in parallel.

20. The method of claim 17, comprising:
serially powering up the one or more memory dies and the interface die.
